(19) United States
(12) Patent Application Publication
(10) Pub. No.: US 2026/0282392 A1
(43) Pub. Date: Sep. 17, 2026

(54) INTEGRATED CIRCUIT STRUCTURE

(71) Applicant: Invention and Collaboration Laboratory, Inc., Taipei City (TW)

(72) Inventor: Chao-Chun Lu, Taipei City (TW)

(73) Assignee: Invention and Collaboration Laboratory, Inc., Taipei City (TW)

(21) Appl. No.: 19/441,862

(22) Filed: Jan. 7, 2026

Related U.S. Application Data
(60) Provisional application No. 63/772,790, filed on Mar. 17, 2025.

(51) Int. Cl. H10B 80/00; H10W 90/00; H10W 90/10; H10W 90/20

(52) U.S. Cl. CPC H10B 80/00; H10W 90/10; H10W 90/288; H10W 90/297; H10W 90/722; H10W 90/724

(57) ABSTRACT

An integrated circuit structure includes a plurality of semiconductor dice and a laterally extending thermal conductivity layer. Each semiconductor die includes a top surface, a bottom surface opposite to the top surface, a first sidewall, a second sidewall, a third sidewall and a fourth sidewall. An area of the bottom surface or the top surface of each semiconductor die is larger than an area of any of the first sidewall, the second sidewall, the third sidewall and the fourth sidewall. The laterally extending thermal conductivity layer covers each second sidewall of the plurality of semiconductor dice. A thermal conductivity of the laterally extending thermal conductivity layer is higher than that of Si. The laterally extending thermal conductivity layer has a bonding surface coupled to the second sidewalls of the plurality of semiconductor dice and an uneven or rough surface which is opposite to the bonding surface.

### CROSS REFERENCE TO RELATED APPLICATIONS

This application claims the benefit of U.S. Provisional Application No. 63/772,790, filed on Mar. 17, 2025. The content of the application is incorporated herein by reference.

### BACKGROUND OF THE INVENTION

### 1. Field of the Invention

The present invention relates to an integrated circuit (IC) structure, and particularly to an integrated circuit structure which can have high performance heat removal capabilities.

### 2. Description of the Prior Art

2.5D/3D ICs have been recognized as a next generation semiconductor technology, which has the advantage of high performance, low power consumption, small physical size and high integration density. 2.5D/3D ICs provide a path to continue to meet the performance/cost demands of next generation devices while remaining at more relaxed gate lengths with less process complexity. Thus, 2.5D/3D ICs are expected to find broad based utilities in applications such as high-performance computing and data centers (HPC), AI (artificial intelligence)/ML (machine learning), 5G/6G networks, graphics, smart phones/wearables, automotive and others that demand “extreme,” ultra-high-performance, higher-power-efficiency devices.

Commercial 2.5D/3D ICs such as a 3D high-bandwidth memory (HBM) DRAM (dynamic random-access memory) memory die stack on logic are increasingly being used, and those HBM structure contain through silicon vias (TSVs) in both active dice and in the silicon interposer. Furthermore, 2.5D/3D ICs also allow for vertical stacking of heterogeneous dice from different manufacturing processes and nodes, chip reuse and chiplets-in-SiP (system-in-a-package) for high-performance applications already pushing the limits of a single die at the most advanced node. As shown in FIG. 1A, a conventional COWOS (chips-on-wafer-on-substrate) structure 100 includes an HBM shelf 102 (with controller 1022) and a logic die (such as graphics processing unit (GPU)) 104 stacked on a Si interposer 106 with through silicon vias (TSVs) 1026, and the Si interposer 106 is then stacked on a packaging substrate 108. In addition, as shown in FIG. 1A, the HBM shelf 102 further includes vertically stacked dynamic random-access memory (DRAM) dice 1024 stacked above the controller 1022. As shown in FIG. 1B, the HBM shelf 102 includes a plurality of DRAM dice 1024 vertically stacked together, each DRAM die has a width 4~6 mm, a length~10.5 mm, and a thinner thickness 0.05~0.1 mm due to the requirement of multiple TSVs 1026 therein. For example, four DRAM dice 1024 are grouped together to output 1 K bits of data bus width, wherein each DRAM die outputs 256 bits, bumps 1028 exist between two adjacent DRAM dice and the controller die 1022 is below and electrically connected to the plurality of vertically stacked DRAM dice.

However, 2.5D/3D ICs adopt packaging topologies with bottom/top areal electrical interconnects created by the interconnect technologies such as micro-bumps, TSV and redistribution layer (RDL). The bottom/top electrical interconnects impose a severe constraint on PPAC (power, performance, area, cost) optimization by designers of 3D ICs to come up with optimal design solutions, especially the difficulty of forming TSVs 1026 in semiconductor dice (the vertically stacked DRAM dice 1024) and the alignment of TSVs 1026 for each semiconductor die.

Furthermore, as the monolithic integration capability of a silicon chip has grown from GSI (giga scale integration: over billions of transistors on a die) toward TSI (tera scale integration: trillions of transistors on a die) soon, the power consumption of running such a huge number of transistors is increasing sharply, which elevates adversely the junction temperature of transistors and thus the entire die temperature due to current limited heat-dissipation capability (e.g. thermal conductivity index of silicon-dioxide/silicon is very low). To be worse, due to the vertically stacked dynamic random-access memory (DRAM) dice 1024 (or HBM) in 2.5D/3D ICs, the insufficient heat dissipation problem causing higher temperature to dice operation is regarded as the worst problem for the HBM structure.

Therefore, the present invention provides several embodiments to solve the above-mentioned disadvantages of the prior art.

### SUMMARY OF THE INVENTION

An embodiment of the present invention provides an integrated circuit (IC) structure. The integrated circuit structure includes a plurality of semiconductor dice and a laterally extending thermal conductivity layer. The plurality of semiconductor dice are separated with each other, wherein each semiconductor die includes a top surface, a bottom surface opposite to the top surface, and four sidewalls with a first sidewall, a second sidewall, a third sidewall and a fourth sidewall; wherein an area of the bottom surface or the top surface of each semiconductor die is larger than an area of any of the first sidewall, the second sidewall, the third sidewall and the fourth sidewall. The laterally extending thermal conductivity layer covers each second sidewall of the plurality of semiconductor dice, wherein the first sidewall is opposite to the second sidewall, and a thermal conductivity of the laterally extending thermal conductivity layer is higher than that of Si. The laterally extending thermal conductivity layer has a bonding surface coupled to the second sidewalls of the plurality of semiconductor dice and an uneven or rough surface which is opposite to the bonding surface.

According to one aspect of the present invention, the IC structure further includes an upward extending thermal conductivity layer attached to a first semiconductor die of the plurality of semiconductor dice; wherein a thermal conductivity of the upward extending thermal conductivity layer is higher than that of Si, and the upward extending thermal conductivity layer is thermally coupled to the laterally extending thermal conductivity layer.

According to one aspect of the present invention, the upward extending thermal conductivity layer is between the first semiconductor die and a second semiconductor die of the plurality of semiconductor dice.

According to one aspect of the present invention, each of the upward extending thermal conductivity layer and/or the laterally extending thermal conductivity layer is a SiC semiconductor die.

According to one aspect of the present invention, the first semiconductor die is the most lateral semiconductor die of the plurality of semiconductor dice, and the upward extending thermal conductivity layer has an uneven or rough surface.

According to one aspect of the present invention, the IC structure further includes an edge RDL with a bonding surface bonded to a plurality of edge pads exposed from the first sidewall of each semiconductor die; wherein the edge RDL includes a plurality edge bumps protruded from an exposed surface opposite to the bonding surface; wherein the plurality of edge pads of a first semiconductor die of the plurality of semiconductor dice are electrically connected to a set of signal pads of the first semiconductor die.

According to one aspect of the present invention, the IC structure further includes a SiC semiconductor die attached to the bottom surface of a first semiconductor die of the plurality of semiconductor dice; wherein a plurality of edge pads exposed from the first sidewall of the first semiconductor die are electrically connected to a set of signal pads of the first semiconductor die, and another plurality of edge pads exposed from a first sidewall of the SiC semiconductor die are electrically connected to another set of signal pads of the first semiconductor die.

According to one aspect of the present invention, the IC structure further includes a logic die, an interposer, a processor die and a packaging substrate. The logic die with memory controller is under and electrically connected to a plurality of edge pads of each semiconductor die, wherein the plurality of edge pads of each semiconductor die are arranged along the first sidewall of the semiconductor die, and each semiconductor die is a dynamic random-access memory (DRAM) semiconductor die. The interposer is under and electrically connected to the logic die. The processor die is disposed on the interposer and electrically connected to the logic die. The packaging substrate is under and electrically connected to the interposer.

According to one aspect of the present invention, the IC structure further includes a logic die with memory controller, a logic die with processor circuit and a packaging substrate. The logic die with memory controller is under and electrically connected to a plurality of edge pads of each semiconductor die, wherein the plurality of edge pads of each semiconductor die are arranged along the first sidewall of the semiconductor die, and each semiconductor die is a dynamic random-access memory (DRAM) semiconductor die. The logic die with processor circuit is disposed over and electrically connected to the logic die with memory controller. The packaging substrate is under and electrically connected to the logic die with memory controller. A die area of the logic die with memory controller is larger than a sum of a horizontal cross-section area of the plurality of semiconductor dice and a die area of the logic die with processor circuit; wherein there is no interposer between the packaging substrate and the logic die with memory controller, and there is no through silicon via (TSV) in each semiconductor die.

According to one aspect of the present invention, the IC structure further includes a logic die with memory controller and processor circuit and a packaging substrate. The logic die with memory controller and processor circuit is under the plurality of semiconductor dice and electrically connected to a plurality of edge pads of each semiconductor die, wherein the plurality of edge pads of each semiconductor die are arranged along the first sidewall of the semiconductor die, and each semiconductor die is a dynamic random-access memory (DRAM) semiconductor die. The packaging substrate is under and electrically connected to the logic die with memory controller and processor. There is no interposer between the packaging substrate and the logic die with memory controller and processor circuit, and there is no TSV in each semiconductor die.

Another embodiment of the present invention provides an IC structure. The IC structure includes a semiconductor die and a thermal conductivity semiconductor layer. The thermal conductivity semiconductor layer covers a top surface of the semiconductor die, wherein a thermal conductivity of the thermal conductivity semiconductor layer is higher than that of Si. The thermal conductivity semiconductor layer has an uneven or rough surface.

According to one aspect of the present invention, a horizontal cross-section area of the thermal conductivity semiconductor layer is the same as that of the top surface of the semiconductor die.

According to one aspect of the present invention, the thermal conductivity semiconductor layer is a SiC semiconductor die with a plurality of fin or pillar structures.

According to one aspect of the present invention, the thermal conductivity semiconductor layer includes SiC, BN, AsN, or AlN.

Another embodiment of the present invention provides an IC structure. The IC structure includes a semiconductor die and a SiC thermal conductivity semiconductor layer. The SiC thermal conductivity semiconductor layer covers a top surface of the semiconductor die. The SiC thermal conductivity semiconductor layer includes a plurality fin or pillar structures, and a depth of the fin or pillar structures is between 1 um and 100 um.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A shows a conventional COWOS (chips-on-wafer-on-substrate) structure.

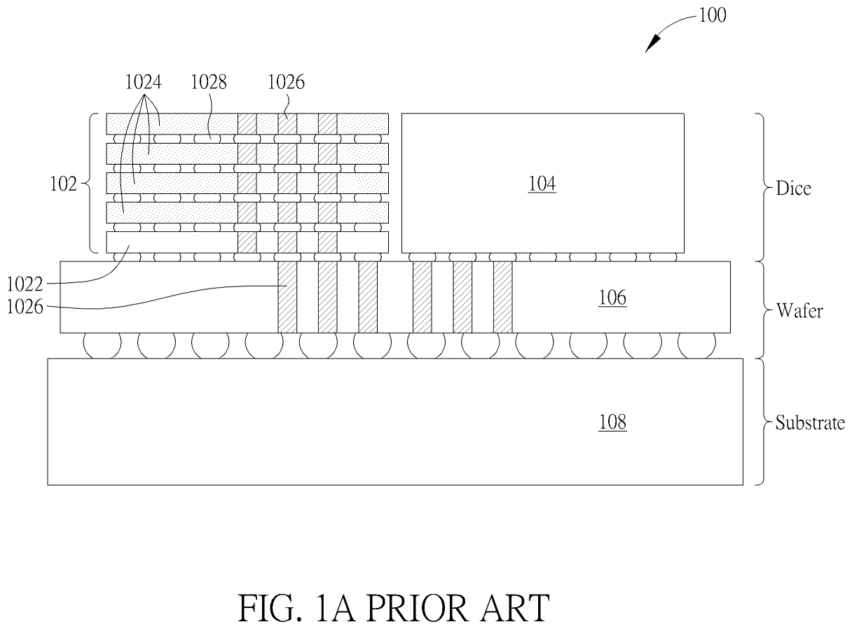

FIG. 1B shows the high-bandwidth memory (HBM) shelf of the conventional COWOS structure.

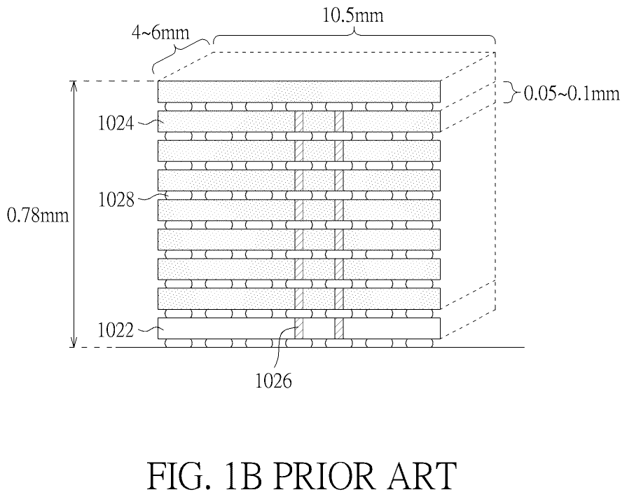

FIG. 2 is a flowchart illustrating a manufacturing process of a new high bandwidth memory (NuHBM) semiconductor die (or logic die) with semiconductor cooling structure which has the uneven or rough surface according to one embodiment of the present invention.

FIG. 3 shows the HTC semiconductor wafer 302 with uneven or rough surface generated from the HTC semiconductor wafer 302 with even surface.

FIG. 4 shows wafer-on-wafer process.

FIG. 5 shows die-on-wafer process.

FIG. 6 shows multiple NuHBM shelves with semiconductor cooling structure stacked on a carrier.

FIG. 7 shows NuHBM shelf with semiconductor cooling structure stacked on sidewall thereof.

FIG. 8A is a perspective view of the NuHBM shelf (or named as NuHBM Stack) with semiconductor cooling structure.

FIG. 8B shows the uneven or rough surface (or fin structure) of the semiconductor cooling structure of the NuHBM shelf being revealed out of a molding material.

FIG. 8C shows the NuHBM shelf including multiple NuHBM dice horizontally stacked together.

FIG. 8D shows the NuHBM shelf having HTC material, top (or laterally) extending HTC material and/or upward extending HTC material with even surface.

FIG. 9A, FIG. 9B show a perspective view and a cross-sectional view of the DRAM die (semiconductor die) according to one embodiment of the present invention.

FIG. 10, FIG. 11, FIG. 12 show the COWOS structures according to different embodiments of the present invention.

### DETAILED DESCRIPTION

The present invention discloses a closely packed HIDS (heterogeneous integrated dice stack) to achieve more heat removal capabilities. The HIDS includes a certain semiconductor material having high thermal conductivity (like SiC) attached to the silicon IC (real die or dice). Using DRAM dice as example, the high thermal conductivity material could be attached to the DRAM die, or disposed between two adjacent DRAM dice and thermally coupled to another high thermal conductivity material covering other side face of DRAM dice stack. Especially, the high thermal conductivity material could be a semiconductor plate with uneven or rough surface. Those uneven or rough surface in the high thermal conductivity (HTC) material could form “fin structures or pillar structures” or “cooling structures” to enhance heat dissipation. Of course, the present invention could be applied to other logic dice stack, rather than only being applied to DRAM dice stack.

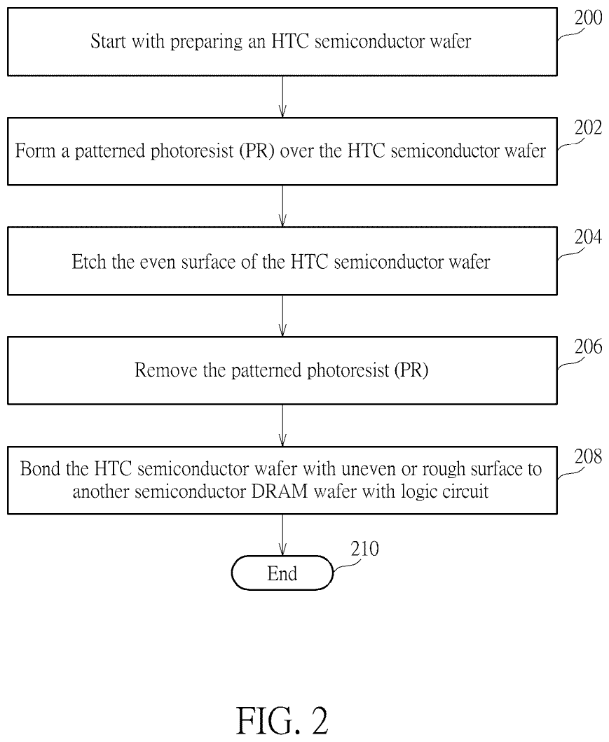

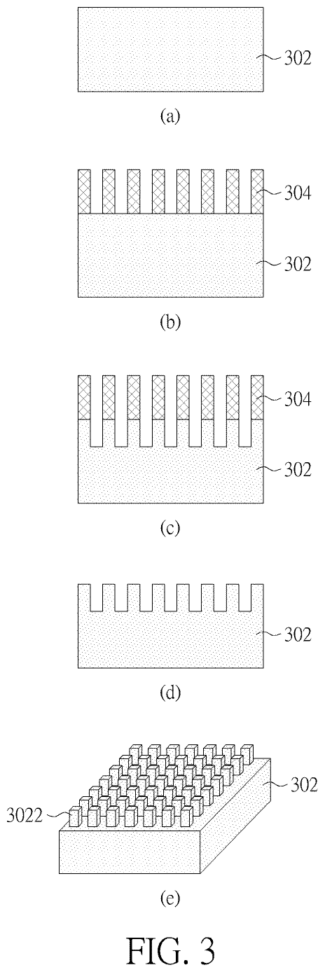

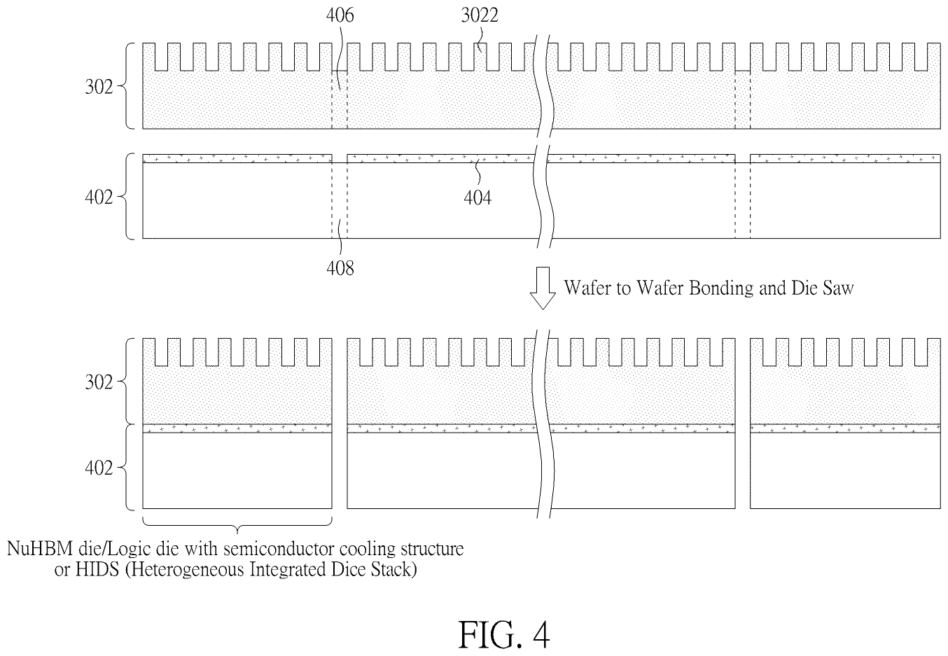

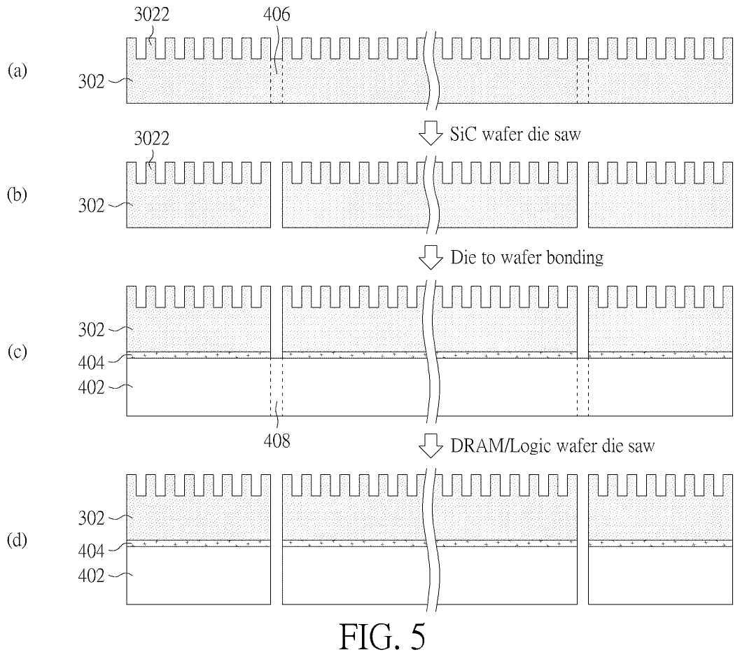

Please refer to FIG. 2, FIG. 3, FIG. 4, FIG. 5, wherein FIG. 2 is a flowchart illustrating a manufacturing process of a semiconductor die with semiconductor cooling structure which has the uneven or rough surface according to one embodiment of the present invention. Detailed steps are as follows:
Step 200: Start with preparing an HTC semiconductor wafer 302 (FIG. 3(a)).
Step 202: Form a patterned mask 304 over the HTC semiconductor wafer 302 (FIG. 3(b)).
Step 204: Etch the surface of the HTC semiconductor wafer 302 (FIG. 3(c)).
Step 206: Remove the patterned mask 304 (FIG. 3(d)).
Step 208: Bond the HTC semiconductor wafer 302 with uneven or rough surface to another semiconductor wafer with circuits (FIG. 4).
Step 210: End.

In Step 200, as shown in FIG. 3(a), the HTC semiconductor wafer 302 with even surface, such as 6″, 8″ or 12″ SiC wafer, is prepared, wherein FIG. 3(a) shows a cross-section view of the HTC semiconductor wafer 302. Then, in Step 202, as shown in FIG. 3(b), the patterned mask 304 is formed over the even surface of the HTC semiconductor wafer 302. The mask could be photoresist mask, or the metal mask (such as Ni, Ti, Cu, or the combination thereof). Then, in Step 204, as shown in FIG. 3(c), according to the patterned PR 304, the surface of the HTC semiconductor wafer 302 is etched. Then, in Step 206, as shown in FIG. 3(d), the patterned mask 304 is removed, so that the HTC semiconductor wafer 302 with uneven or rough surface is formed. As shown in FIG. 3(e), the uneven or rough surface of the HTC semiconductor wafer 302 could form “fin structures” 3022 and a top surface of each of the “fin structures” 3022 can have rectangle, or circle, or hexagon, wherein FIG. 3(e) shows a 3-dimensional perspective view of the HTC semiconductor wafer 302 with uneven or rough surface. The depth of the fin structures could be 1~100 um, depending on the etching rate and the etching solution.

Afterward, in Step 208, as shown in FIG. 4 (Wafer-on-Wafer process), the HTC semiconductor wafer 302 with uneven or rough surface could be first bonded (e.g. through an adhesive 404) to another semiconductor wafer (such as Si wafer with logic circuits or memory circuits) 402, and then the two bonded wafers (the HTC semiconductor wafer 302 and the another semiconductor wafer 402) are then diced along scribe lines 406, 408 to form discrete semiconductor die with semiconductor cooling structure which has the uneven or rough surface. After dicing, the discrete semiconductor die could be a logic die or a memory die, and the semiconductor cooling structure could be the SiC heat remover. The discrete semiconductor die with semiconductor cooling structure is also named as Heterogeneous Integrated (HI) Dice Stack (HIDS), and the scribe lines 406, 408 are aligned with each other.

As mentioned, the semiconductor cooling structure with uneven or rough surface or fin structures could be applied or attached to the semiconductor die with logic circuit, or to the DRAM memory die. Thus, as shown in FIG. 4, the result is that a SiC die (i.e. the HTC semiconductor wafer 302) with a cooling fin structure has a good alignment to the underlying semiconductor die as a HIDS with effective SiC heat remover inside it.

On the other hand, FIG. 5 shows die-on-wafer process according to another embodiment of the present invention. As shown in FIG. 5(a), FIG. 5(b), continuing from FIG. 3(d), first, dice the HTC semiconductor wafer 302 with “fin structures” along the scribe lines 406 to generate scribed SiC heat removing dice, and then as shown in FIG. 5(c), place the scribed SiC heat removing dice on a top of the semiconductor wafer 402 (i.e. the semiconductor wafer with logic circuits or memory circuits) by aligning the SiC heat removing die to the corresponding location of the semiconductor wafer with a suitable glue processing (adhesive glue 404), and then as shown in FIG. 5(d), according to the scribe lines 408, use the appropriate die-saw technique to cut the SiC heat remover-on-semiconductor die together to create the Heterogeneous Integrated (HI) Dice Stack (HIDS) or Heterogeneous Integrated Dice Cooling Structure (HIDCS), wherein the HIDS can be used like Chiplet for future dice or packaged-chip application but has the high cooling capability.

In the HIDS or HIDCS, there could be more than one semiconductor dice horizontally or vertically stacked together, and then more than one SiC heat removers are bonded to the semiconductor dice stack. That is, more than one SiC heat removers could be bonded to the semiconductor dice stack. For example, an appropriate package technique to pack this HIDS die into a package with effective pins, or leave this HIDS in a die form (or like a Chiplets) for the subsequent microsystem needs. Such a SiC heat remover (the semiconductor cooling structure with fin structures) can be positioned on top of the real die area as described above, or place on the side edge of the die area and/or at the bottom of the die area, or in between two semiconductor dice if the stack contains multiple semiconductor dice which can dissipate the heat from all sides of the real die product to add more heat removal capabilities.

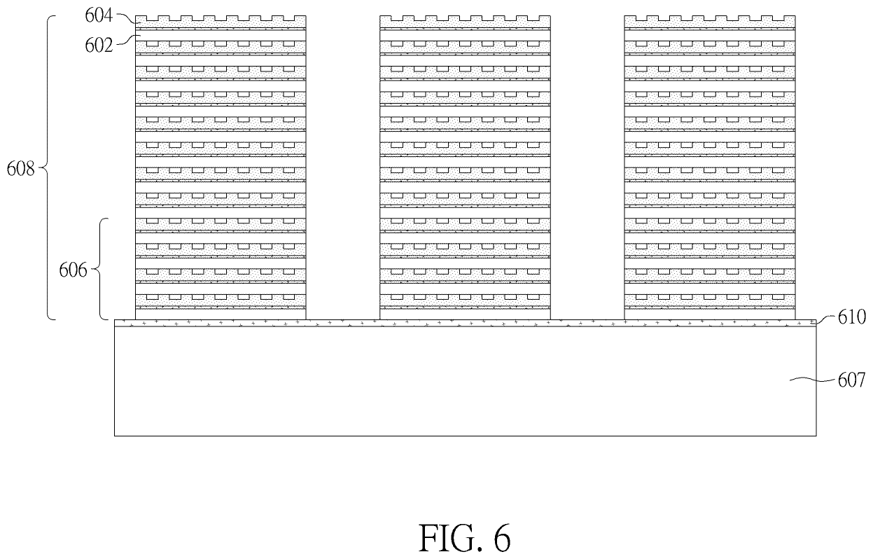

Next, in one embodiment of the present invention, when the semiconductor die is a DRAM die or a new high bandwidth memory (NuHBM) die with edge pads on the sidewall of the NuHBM, the NuHBM stack or shelve can be formed, followed by:
(1) As shown in FIG. 6, vertically stack more HIDS (each includes a NuHBM die 602 and a semiconductor cooling structure 604) to form the short NuHBM stack 606 on a carrier 607. In one embodiment, the thermal conductivity (or thermal conductivity coefficient) of the high thermal conductivity layer or the semiconductor cooling structure is higher than that of Si or SiO₂.
(2) Then, combine multiple short NuHBM stacks 606 together to form a NuHBM shelf 608 which are thick enough for ease of subsequent formation processing, wherein a release layer 610 exists between the NuHBM shelves 608 and the carrier 607.

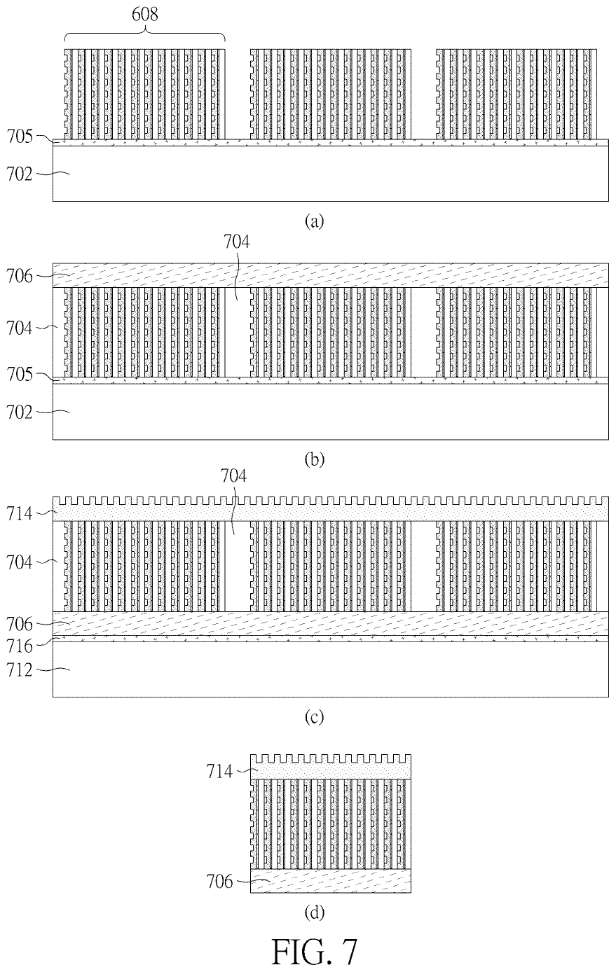

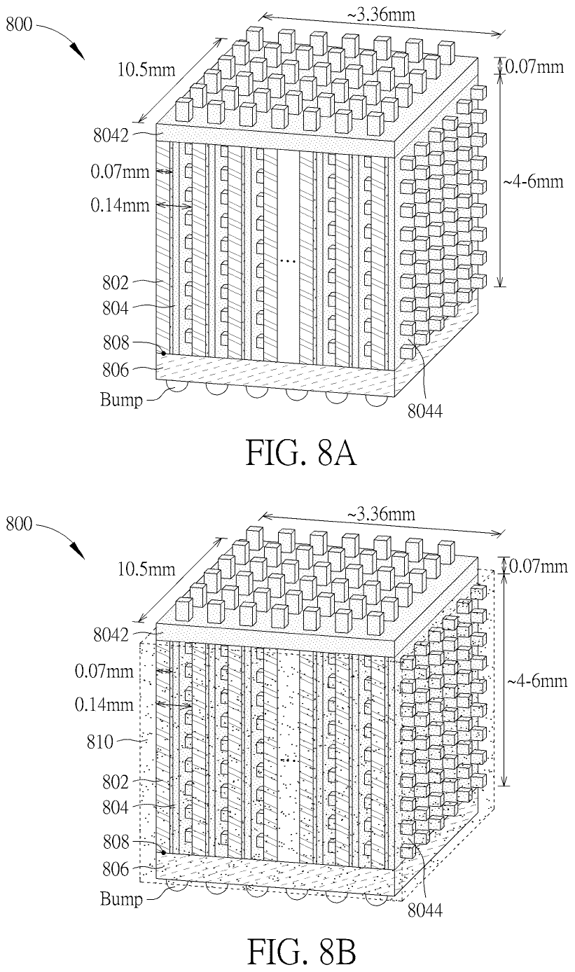

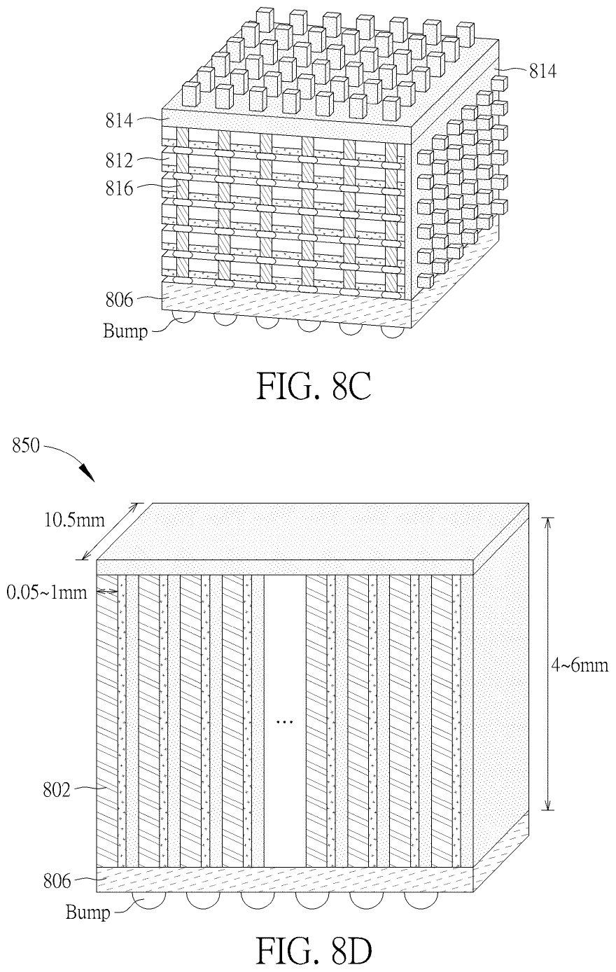

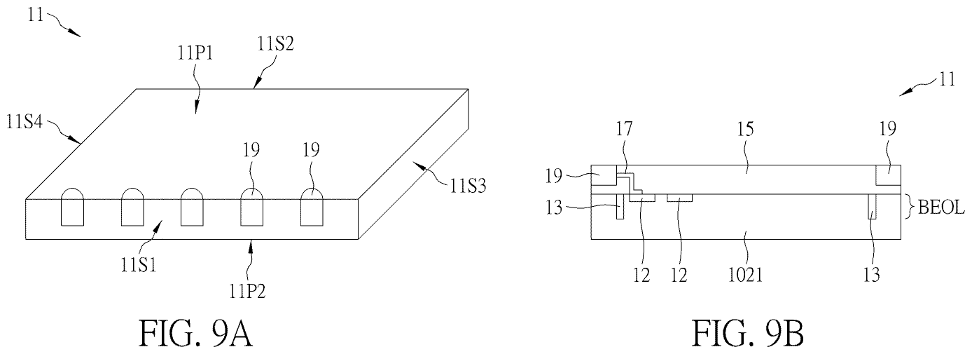

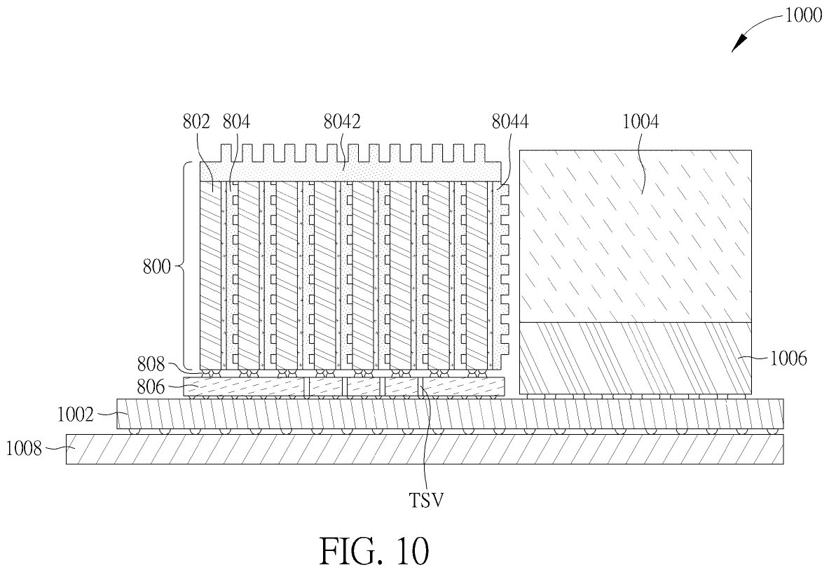

In another embodiment of the present invention, as shown in FIG. 7(a), the NuHBM shelves 608 can be rotated and bonded sideways to another carrier 702 and potted them using a polymer material 704 (such as the Epotek 377 epoxy) in vacuum and curing the polymer material 704, followed by:
(1) As shown in FIG. 7(a), FIG. 7(b), rotate and bond the multiple NuHBM shelves 608 to the carrier 702, then fill and cure the polymer material 704 in vacuum between the NuHBM shelves 608, and then planarize (and a light etch or lap to ensure all edge connections are revealed) the polymer material 704, wherein a release layer 705 exists between the NuHBM shelves 608 and the carrier 702.
(2) As shown in FIG. 7(b), bond the multiple NuHBM shelves 608 with a base logic die wafer 706 (or other logic wafer 706).
(3) As shown in FIG. 7(c), bond a carrier 712 and release the carrier 702, and use a top or laterally extending high thermal conductivity layer 714 to cover the multiple NuHBM shelves 608 (or create an extending high thermal conductivity layer to cover other one/two/three sidewalls of the NuHBM shelves 608; or to cover the rest sidewalls of the NuHBM shelves 608), wherein the top or laterally extending high thermal conductivity layer 714 can be referred to the HTC semiconductor wafer 302 with uneven or rough surface, and a release layer 716 exists between the base logic die wafer 706 and the carrier 712.
(4) As shown in FIG. 7(d), release the carrier 712, and dice and release the NuHBM shelf 608 with semiconductor cooling structure, wherein the NuHBM shelf 608 is bonded to the base logic die (or a memory controller die).
FIG. 8A is a perspective view of the NuHBM shelf (or named as NuHBM Stack) 800 with semiconductor cooling structure, in which the thickness of one NuHBM die 802 could be about 0.05~0.2 mm (such as 0.07 mm) and the thickness of one semiconductor cooling structure 804 could be about 0.05~0.2 mm (such as 0.07 mm as well), thus the thickness of one NuHBM die 802 with semiconductor cooling structure 804 is around 0.1~0.4 mm (such as 0.14 mm). In addition, the NuHBM shelf 800 further includes other semiconductor cooling structures with uneven or rough surface (such as a laterally extending high thermal conductivity (HTC) material 8042 and an upward extending high thermal conductivity (HTC) material 8044) which have large surface for heat dissipation, wherein the laterally extending high thermal conductivity (HTC) material 8042 covers a top of the NuHBM shelf 800 and couple to the semiconductor cooling structure 804 between the NuHBM dice, the upward extending high thermal conductivity (HTC) material 8044 is located on the most lateral sidewall(s) of the NuHBM shelf 800, and the semiconductor cooling structure 804, the top high thermal conductivity (HTC) material 8042 and the upward extending high thermal conductivity (HTC) material 8044 can be SiC/AlN/BN/W/Cu/Cu/Al/large grain silicon/undoped silicon, and so on. As shown in FIG. 8A, for example, there are 24 NuHBM dice (horizontally stacked together) with 24 semiconductor cooling structures 804 in the NuHBM shelf 800, wherein the width and the length thereof are around 3.36 mm and 10.5 mm respectively. The height of the NuHBM shelf 800 with the top semiconductor cooling structure is around 4~6 mm. Since the top semiconductor cooling structure in the NuHBM shelf 800 has uneven or rough surface, and the most lateral semiconductor cooling structure in the NuHBM shelf 800 has uneven or rough surface as well, heat dissipation efficiency for the NuHBM shelf 800 could be enhanced. As shown in FIG. 8A, the NuHBM shelf 800 together with a base die or memory controller 806 thereunder is a “chiplet” for the subsequent microsystem needs, and could be packaged with molding material if necessary. In addition, each NuHBM die in the NuHBM shelf 800 has a width around 4~6 mm, a length~10.5 mm, and a regular thickness of 0.05~0.1 mm without TSV therein. As shown in FIG. 8A, a plurality of edge pads 808 are arranged along the length~10.5 mm, for example, when the hybrid bonding with bonding pitch~5 um is used, each NuHBM die has 2100 edge pads (10.5 mm/5 um=2100) with 1K bits data input/output (I/O); and when conventional solder ball bonding with bonding pitch~40 um is used, each NuHBM chip has 262 edge pads (10.5 mm/40 um=262) with around 128 bits data I/Os. If necessary, an edge RDL could be optionally used for the formation of edge pads. Therefore, each NuHBM die could has 256 bits data output, or other number of edge pads if necessary. Therefore, when the NuHBM shelf 800 (including the plurality of NuHBM dice 802) is electrically coupled to the base die or memory controller 806 through the plurality of edge pads 808, such that the base die or memory controller 806 can output the desired data width based on data output of one NuHBM die 802, combination data output of two or more NuHBM dice 802, or combination data output of all NuHBM dice 802. In addition, as shown in FIG. 8B, the uneven or rough surface (or fin structure) of the semiconductor cooling structure of the NuHBM shelf 800 may be revealed out of a molding material 810.

Although the NuHBM shelf 800 includes multiple NuHBM dice 802 horizontally stacked together, in another embodiment of the HIDS, as shown in FIG. 8C, there could be more than one Si dice (e.g. DRAM die) 812 vertically stacked together, and then more than one SiC heat removers (semiconductor cooling structures) 814 are bonded to the top of Si dice stack. As shown in FIG. 8C, multiple Si dice are vertically stacked together, and then one or more SiC heat removers (semiconductor cooling structures) 814 are bonded to the Si dice stack (such as HBM bonded to IC heat removers) to form another HIDS or “chiplets”. In addition, as shown in FIG. 8C, because the Si dice 812 are vertically stacked together, there are still TSVs 816 in the Si dice 812.

The above-mentioned HIDS or “chiplets” could be used in any 2.5D/3D IC structure. In another embodiment, as shown in FIG. 8D, each NuHBM die of the NuHBM shelf 850 is bonded to an HTC material 816 (i.e. SiC semiconductor cooling structure) which has even surface and includes top (or laterally) extending HTC material and/or upward extending HTC material, rather than uneven or rough surface. However, the NuHBM shelf 850 may still have (1) top semiconductor cooling structure with uneven or rough surface, and/or (2) upward extending semiconductor cooling structure with uneven or rough surface located on the most lateral sidewall(s) of the NuHBM shelf 850. In another embodiment, there is no HTC material or semiconductor cooling structure between two NuHBM dice, but NuHBM shelf still has (1) top semiconductor cooling structure with uneven or rough surface, and/or (2) upward extending semiconductor cooling structure with uneven or rough surface located on the most lateral sidewall(s) of the NuHBM shelf.

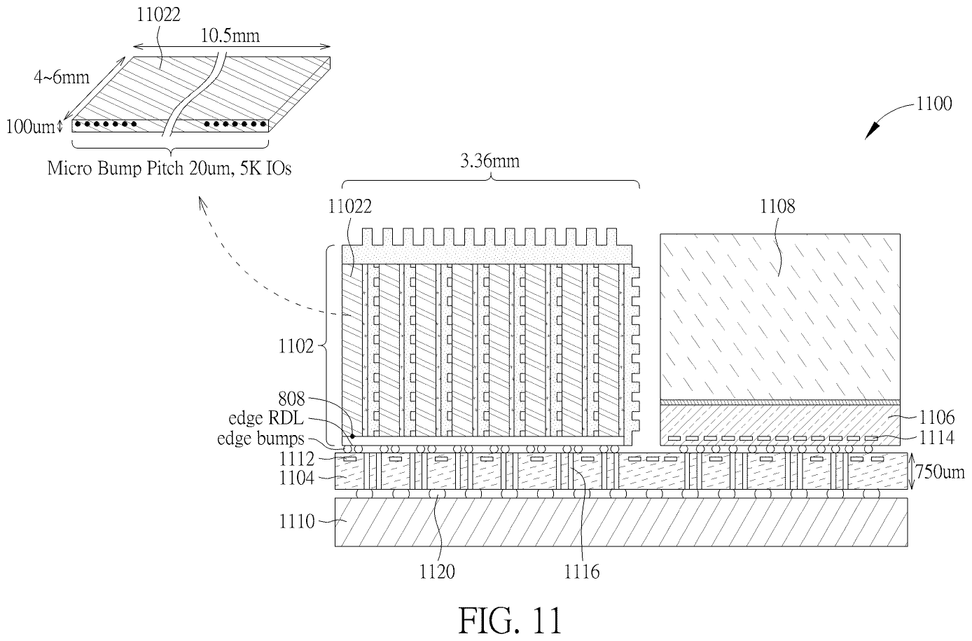

In addition, as shown in FIG. 8A, it is noted that the NuHBM shelf 800 includes a plurality of DRAM dice horizontally stacked together, each DRAM die could have edge pads on the sidewall surfaces thereof, and there is no TSVs in the NuHBM shelf 800. Next, please refer to FIG. 9A, FIG. 9B, wherein FIG. 9A, FIG. 9B take one NuHBM die 11 of the NuHBM shelf 800 as an example. FIG. 9A, FIG. 9B show a perspective view and a cross-sectional view of the DRAM die (semiconductor die) 11 according to one embodiment of the present invention, respectively. The NuHBM die 11 has a top surface 11P1, a bottom surface 11P2, and four sidewalls 11S1, 11S2, 11S3, and 11S4, wherein the area of the top surface/bottom surface 11P1/11P2 is far larger than those of the sidewalls 11S1, 11S2, 11S3, and 11S4 (as shown in FIG. 9A). The semiconductor die 11 further includes “edge pads” 19 in the form of peripheral pads residing at the periphery or side faces or sidewalls (such as sidewalls 11S1, 11S2, 11S3, and/or 11S4) of the DRAM die 11 in FIG. 9A.

Referring to FIG. 9B, in one embodiment, the NuHBM die 11 includes a memory cell die 1021 and a redistribution layer (RDL) 15 over a top surface of the memory cell die 1021. In one embodiment, there is no TSV in the memory cell die 1021 of the DRAM die 11 which includes edge pads along the side surface. There are one or more signal pads 12 within the memory cell die 1021, and a seal ring 13 surrounding the signal pads 12. The memory cell die 1021 may include a BEOL (back end of line) region arranged on a front side of the memory cell die 1021. In one embodiment, each edge pad 19 of each NuHBM die 11 is connected to the conductive line 17 in the redistribution layer 15, and the conductive line 17 is electrically connected to the signal pad 12 in the back-end-of-line (BEOL) region of the DRAM die 11 surrounded by the seal ring 31. Thus, the exposed surface of the edge pad 19 is out of the peripheral of the seal ring 13. Referring to FIG. 9B, in the substrate of the memory cell die 1021, all signal pads 12 are located within a region defined by the seal ring 13 of the substrate, and the edge pads 19 are located in the RDL 15 and electrically connected to the signal pads 12 (see of FIG. 9B) in the BEOL region.

In another embodiment of the present invention, the interconnect structure of the RDL 15 may include a plurality of conductive lines, a plurality of conductive vias, and one or more edge pads 19. The conductive lines, conductive vias and edge pads together construct the various conduction paths of the interconnect structure.

In another embodiment, there could be an edge RDL (not shown) with a bonding surface bonded to the first sidewall of each semiconductor die and the plurality of edge pads 19 exposed from the RDL 15 of the semiconductor die. The edge RDL comprises a plurality edge bumps protruded from an exposed surface of the edge RDL opposite to the bonding surface.

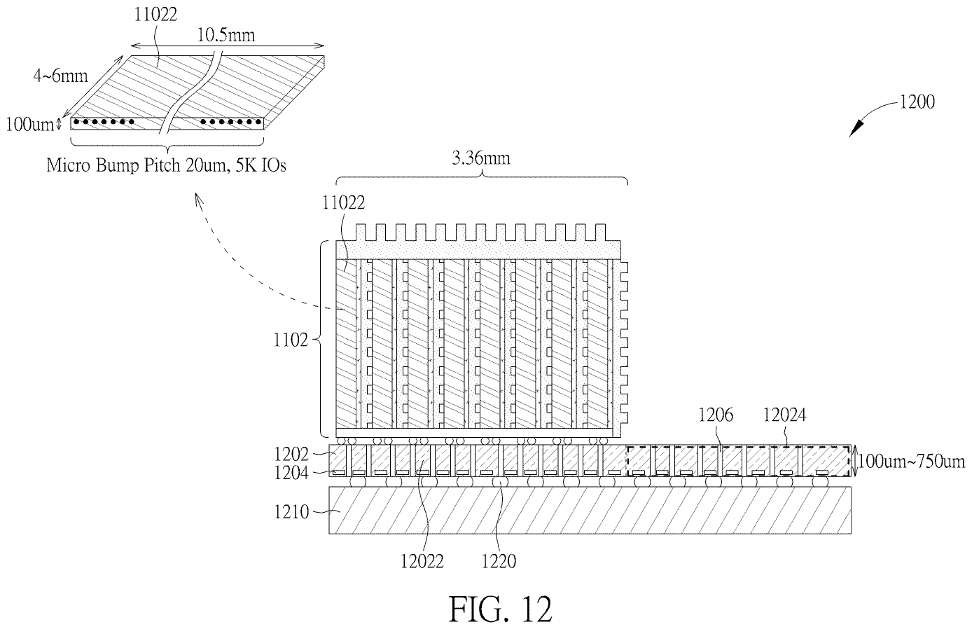

It is noted that the NuHBM shelf (e.g. the NuHBM shelf 800) with semiconductor cooling structures provided by the present invention could replace the conventional HBMs in the COWOS structure. Next, as shown in FIG. 10, the NuHBM shelf 800 (of the COWOS structure 1000) with semiconductor cooling structures is bonded to the base die or memory controller 806 which then can be bonded to another interposer (or IC chip) 1002, wherein the NuHBM shelf 800 with semiconductor cooling structures includes a plurality of NuHBM dice 802, each NuHBM die 802 is horizontally separate from the others. The power/signals of each NuHBM die 802 could be propagated to the base die or memory controller 806 without through other NuHBM dice. Furthermore, each NuHBM die includes a plurality of edge pads 808 revealed or protruded from the sidewall of the NuHBM die, and electrically connected to the signal pads of the NuHBM die through the RDL 15 (referring to FIG. 9B). Alternatively, the NuHBM shelf 800 further includes a plurality of edge pads/bumps extended or protruded from another edge RDL (not shown) bonded to the sidewall of the NuHBM die, and electrically connected to the signal pads of the NuHBM die through the RDL 15.

In another embodiment, there could be another plurality of edge pads (not shown) revealed or protruded from the sidewall of the semiconductor cooling structure 804 which is adjacent to the NuHBM die, and electrically connected to the signal pads of the NuHBM die through the RDL 15 of the NuHBM die and another regular RDL of the semiconductor cooling structure 804. Alternatively, the NuHBM shelf 800 further includes another plurality of edge pads/bumps (not shown) extended or protruded from another edge RDL bonded to the sidewall of the semiconductor cooling structure 804, and electrically connected to the signal pads of the NuHBM die through the RDL 15 of the NuHBM die and another regular RDL of the semiconductor cooling structure 804.

Moreover, there is an inter-semiconductor cooling structure (i.e. the semiconductor cooling structure 804 which for example can be AlN, BN, AsN, or SiC with uneven/rough surface) between two adjacent NuHBM dice 802 and optionally connected to the top high thermal conductivity (HTC) material 8042 on the top surface of the NuHBM shelf 800. Thus, the heat generated from those two NuHBM dice could be spread through the inter-semiconductor cooling structure 804 to the top high thermal conductivity (HTC) material 8042 with uneven/rough surface, and passed to other heat sink (not shown) thermally coupled to the top high thermal conductivity (HTC) material 8042. In addition, as shown in FIG. 10, the heat generated from the NuHBM dice of the NuHBM shelf 800 could be also spread through the inter-semiconductor cooling structure (i.e. the semiconductor cooling structure 804) to the upward extending high thermal conductivity (HTC) material 8044 with uneven/rough surface. In addition, as shown in FIG. 10, there is another heat sink 1004 above and thermally coupled to a processing unit (such as CPU, GPU, or TPU, etc.) 1006 of the COWOS structure 1000 to dissipate heat generated from the processing unit 1006, wherein the processing unit 1006 is also boned to the interposer 1002. The heat sink 1004 and the processing unit 1006 are horizontally separated from the NuHBM shelf 800, and the interposer 1002 is then stacked on the packaging substrate 1008.

In another embodiment of the present invention, as shown in

FIG. 11, in another IC structure 1100, the NuHBM shelf 1102 can be boned to another logic IC die 1104 with memory controller, wherein the NuHBM shelf 1102 can be referred to the NuHBM shelf 800. The power/control/data signals of each NuHBM die (e.g. a NuHBM die (DRAM die) 11022) of the NuHBM shelf 1102 could be propagated to the logic IC die 1104 without through other NuHBM dice. Moreover, an area of the logic IC die 1104 is large enough to accommodate both the NuHBM shelf 1102 and another system-on-chip (SOC) die 1106 (such as central processing unit (CPU), GPU, or TPU etc.) bonded to the logic IC die 1104. The area of the logic IC die 1104 is dependent on the size and number of the NuHBM shelf 1102 and the SOC die 1106, and the area of the logic IC die 1104 is usually greater than the sum of the horizontal cross-section area of the NuHBM shelf 1102 and the area of the system-on-chip (SOC) die 1106. Furthermore, it is possible that there are two or more NuHBM shelves on the logic IC die 1104. There could be a heat sink 1108 over the SOC die 1106, such that the top surface of the heat sink 1108 could be leveled up with the top surface of the NuHBM shelf 1102. To be mentioned, FIG. 11 is just sketched and exemplary drawings, the components in those drawings may not be proportional to the real size. In addition, as shown in FIG. 11, the logic IC die 1104 is then stacked on the packaging substrate 1110.

In addition, as shown in FIG. 11, since both the SOC die 1106 and the NuHBM shelf 1102 are designed to be disposed over the top surface of the logic IC die 1104 with memory controller, their IOs are well connected by monolithic interconnections. The outgoing pads of the SOC die 1106 are made in the electrical connection to the packaging substrate 1110 through the logic IC die 1104 with memory controller. On the same logic IC die 1104, the NuHBM controller circuits are designed at the front surface (shown by dash line 1112 with BEOL), well connected to the IOs of the SOC die 1106 designed at the bottom surface (shown by the dash line 1114 with BEOL). In the area of the logic IC die 1104, TSVs 1116 are made vertically across the die thickness and micro bumps (or hybrid bumps) are made on the both ends of TSVs 1116. The IOs of the SOC die 1106 could be electrically connected to the IOs edge pads 808 of the NuHBM shelf 1102 through the logic IC die 1104 with memory controller. Then the logic IC die 1104 with memory controller having micro bumps (or hybrid bumps) on the surface thereof is electrically connected to the bumps 1120 of the packaging substrate 1110 by the correctly designed alignment.

In another embodiment of the present invention, as shown in FIG. 12, in another IC structure 1200, the SOC die 1106 in FIG. 11 is embedded into the logic die 1202 with memory controller. That is, the logic die 1202 under the NuHBM shelf 1102 includes not only the memory controller 12022, but also the SOC die 12024 (such as GPU, CPU, neural network processing unit (NPU), tensor processing unit (TPU), field programmable gate array (FPGA), etc.), and the memory controller 12022 of the logic die 1202 could be disposed right under the NuHBM shelf 1102. As shown in FIG. 12, the logic die 1202 is disposed on the packaging substrate 1210 by flip-chip way. That is, the memory controller 12022 and the SOC die 12024 of the logic die 1202 are designed at the bottom surface (shown by dash line 1204 with BEOL), wherein there are bumps 1220 between the logic die 1202 and the packaging substrate 1210. There are TSVs 1206 penetrating through the logic die 1202 with the memory controller and the SOC die, especially from the memory controller 12022 to the NuHBM shelf 1102. Of course, there could be a heat sink (not shown) over the SOC die area of the logic die 1202, such that the top surface of the heat sink could be leveled up with the top surface of the NuHBM shelf 1102. Similarly, FIG. 12 is just sketched and exemplary drawings, the components in those drawings may not be proportional to the real size. Although the logic die 1202 with the memory controller and SOC die is faced down (shown by dash line 1204 with BEOL in FIG. 12), in another example the logic die 1202 with the memory controller and SOC die could be faced up. Since there are TSVs 1206 in the logic die 1202 with the memory controller and SOC die, the logic die 1202 with the memory controller and SOC die could be electrically connected to the packaging substrate 1210 through the TSVs 1206. Moreover, the signal and the power connections/transmissions in the present invention could be either based on the logic die 1202, or based on the packaging substrate 1210 (through the logic die 1202).

In the event there is a need to have more signals transmission in the IC structure 1200, as previously mentioned, more edge RDLs could be formed on two or more sidewalls of the NuHBM shelf 1102. In the event there is a need to have more heat dissipation requirement, as previously mentioned, more high thermal conductivity layers could be formed on two or more sidewalls of the NuHBM shelf 1102.

In summary, the present invention provides a closely packed HIDS (Heterogeneous Integrated Dice Stack) to achieve more heat removal capabilities. The HIDS includes a certain semiconductor material having high thermal conductivity (like SiC) attached to the semiconductor IC die (real IC die). Although most commonly used heat removal materials are metals such as copper, aluminum, etc. but it has high risks of electrical shorts between the heating pads with real IC die if they are closely packed together. In addition, the conventional composite stack further including metal layer can hardly sustain through subsequent processes with high temperatures. Nevertheless, the present invention of using semiconductor materials which can sustain high temperature with high electrical resistivity (such as SiC, AlN, AsN, BN, etc.) in a HIDS has no such concern. Using lithography and etching techniques to create an uneven structure (such as fin structure) on semiconductor cooling material which can significantly increase the thermal dissipation areas to enhance the heat removal efficiency. Thus, forming such a HIDS, which facilitates the use of a heterogeneous integrated (HI) microsystem, opens the door to heterogeneous integration.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. An integrated circuit (IC) structure comprising:
a plurality of semiconductor dice separated with each other, wherein each semiconductor die comprises a top surface, a bottom surface opposite to the top surface, and four sidewalls with a first sidewall, a second sidewall, a third sidewall and a fourth sidewall; wherein an area of the bottom surface or the top surface of each semiconductor die is larger than an area of any of the first sidewall, the second sidewall, the third sidewall and the fourth sidewall; and
a laterally extending thermal conductivity layer covering each second sidewall of the plurality of semiconductor dice, wherein the first sidewall is opposite to the second sidewall, and a thermal conductivity of the laterally extending thermal conductivity layer is higher than that of Si;
wherein the laterally extending thermal conductivity layer has a bonding surface coupled to the second sidewalls of the plurality of semiconductor dice and an uneven or rough surface which is opposite to the bonding surface.

2. The IC structure of claim 1, further comprising an upward extending thermal conductivity layer attached to a first semiconductor die of the plurality of semiconductor dice;
wherein a thermal conductivity of the upward extending thermal conductivity layer is higher than that of Si, and the upward extending thermal conductivity layer is thermally coupled to the laterally extending thermal conductivity layer.

3. The IC structure of claim 2, wherein the upward extending thermal conductivity layer is between the first semiconductor die and a second semiconductor die of the plurality of semiconductor dice.

4. The IC structure of claim 3, wherein each of the upward extending thermal conductivity layer and/or the laterally extending thermal conductivity layer is a SiC semiconductor die.

5. The IC structure of claim 2, wherein the first semiconductor die is the most lateral semiconductor die of the plurality of semiconductor dice, and the upward extending thermal conductivity layer has an uneven or rough surface.

6. The IC structure of claim 1, further comprising an edge RDL with a bonding surface bonded to a plurality of edge pads exposed from the first sidewall of each semiconductor die; wherein the edge RDL comprises a plurality edge bumps protruded from an exposed surface opposite to the bonding surface; wherein the plurality of edge pads of a first semiconductor die of the plurality of semiconductor dice are electrically connected to a set of signal pads of the first semiconductor die.

7. The IC structure of claim 1, further comprising a SiC semiconductor die attached to the bottom surface of a first semiconductor die of the plurality of semiconductor dice; wherein a plurality of edge pads exposed from the first sidewall of the first semiconductor die are electrically connected to a set of signal pads of the first semiconductor die, and another plurality of edge pads exposed from a first sidewall of the SiC semiconductor die are electrically connected to another set of signal pads of the first semiconductor die.

8. The IC structure of claim 1, further comprising:
a logic die under and electrically connected to a plurality of edge pads of each semiconductor die; wherein the plurality of edge pads of each semiconductor die are arranged along the first sidewall of the semiconductor die, and each semiconductor die is a dynamic random-access memory (DRAM) semiconductor die;
an interposer under and electrically connected to the logic die;
a processor die disposed on the interposer and electrically connected to the logic die; and
a packaging substrate under and electrically connected to the interposer.

9. The IC structure of claim 1, further comprising:
a logic die with memory controller under and electrically connected to a plurality of edge pads of each semiconductor die; wherein the plurality of edge pads of each semiconductor die are arranged along the first sidewall of the semiconductor die, and each semiconductor die is a dynamic random-access memory (DRAM) semiconductor die;
a logic die with processor circuit disposed over and electrically connected to the logic die with memory controller; and
a packaging substrate under and electrically connected to the logic die with memory controller;
wherein a die area of the logic die with memory controller is larger than a sum of a horizontal cross-section area of the plurality of semiconductor dice and a die area of the logic die with processor circuit; wherein there is no interposer between the packaging substrate and the logic die with memory controller, and there is no through silicon via (TSV) in each semiconductor die.

10. The IC structure of claim 1, further comprising:
a logic die with memory controller and processor circuit under the plurality of semiconductor dice and electrically connected to a plurality of edge pads of each semiconductor die; wherein the plurality of edge pads of each semiconductor die are arranged along the first sidewall of the semiconductor die, and each semiconductor die is a dynamic random-access memory (DRAM) semiconductor die; and
a packaging substrate under and electrically connected to the logic die with memory controller and processor;
wherein there is no interposer between the packaging substrate and the logic die with memory controller and processor circuit, and there is no TSV in each semiconductor die.

11. An IC structure comprising:
a semiconductor die; and
a thermal conductivity semiconductor layer covering a top surface of the semiconductor die, wherein a thermal conductivity of the thermal conductivity semiconductor layer is higher than that of Si;
wherein the thermal conductivity semiconductor layer has an uneven or rough surface.

12. The IC structure of claim 11, wherein a horizontal cross-section area of the thermal conductivity semiconductor layer is the same as that of the top surface of the semiconductor die.

13. The IC structure of claim 11, wherein the thermal conductivity semiconductor layer is a SiC semiconductor die with a plurality of fin or pillar structures.

14. The IC structure of claim 11, wherein the thermal conductivity semiconductor layer comprises SiC, BN, AsN, or AlN.

15. An IC structure comprising:
a semiconductor die; and
a SiC thermal conductivity semiconductor layer covering a top surface of the semiconductor die;
wherein the SiC thermal conductivity semiconductor layer comprises a plurality fin or pillar structures, and a depth of the fin or pillar structures is between 1 um and 100 um.
